(19) United States
(12) Patent Application Publication
(10) Pub. No.: US 2025/0133681 A1
(43) Pub. Date: Apr. 24, 2025

(54) FASTENER ASSEMBLY TO REMOVABLY FASTEN A RISER CAGE ASSEMBLY TO AN ELECTRONIC DEVICE

(71) Applicant: HEWLETT PACKARD ENTERPRISE DEVELOPMENT LP, Spring, TX (US)

(72) Inventors: Chen-Ruei Tu, Taipei (TW); Jui Lin Chen, Taipei (TW)

(21) Appl. No.: 18/491,387

(22) Filed: Oct. 20, 2023

(51) Int. Cl. H05K 7/14; F16B 21/04

(52) U.S. Cl. CPC H05K 7/1489; F16B 21/04

(57) ABSTRACT

A riser cage assembly having a riser cage bracket and a fastener assembly coupled to the riser cage bracket is disclosed. The fastener assembly includes an enclosure, an actuator including drivers, a shaft, and a biasing member. The enclosure has a bore, guide teeth within the bore, and bays defined between the guide teeth. The actuator is movably coupled to an end of the enclosure with the drivers disposed within the bore. The shaft has blades disposed within the bore, and a locking arm protruding beyond the bore from another end of the enclosure. The actuator generates biasing force urging the shaft towards the end of the enclosure. The shaft is translatable along and rotatable along a vertical axis relative to the enclosure, by the actuator and the biasing member to removably fasten the riser cage bracket to the electronic device.

### BACKGROUND

An electronic device such as a computer, a networking device, or the like includes electronic components such as power supply units, storage drives, PCIe drives, and a primary system board (e.g., a motherboard) having hardware components such as central processor units, resistors, capacitors, or the like to provide some basic function. However, to pursue stronger performance and/or expand the functionality of the electronic device, additional electronic components such as an expansion card can be detachably connected to the primary system board via an expansion connector on the primary system board. In some electronic devices, an expansion card is connected directly to the expansion connector of the primary system board. However, in other electronic devices, it may not be possible to directly connect the expansion card to the expansion connector (e.g., due to orientation or space constraints, and/or due to the connectors being incompatible), and thus the expansion card may be coupled to another electronic component such as a riser card which is in turn connected to the expansion connector of the primary system board. The riser card carries one electrical connector that is suitable for receiving the expansion card and another connector suitable for being detachably connected to the expansion connector of the primary system board, and these connectors are arranged such that, when everything is connected, the expansion card fits as desired within the space constraints of the system.

For example, in some devices the expansion connectors of the primary system board are oriented to receive expansion cards extending perpendicularly to the primary system board, but in low-profile devices (e.g., 1U or 2U servers), there may not be sufficient vertical clearance for an expansion card to be oriented perpendicular to the primary system board. Thus, in some of these devices, the riser card may extent perpendicular to the primary system board and have a connector arranged to receive the expansion card in an orientation parallel to the primary system board, thus allowing the expansion card to fit within the low-profile device.

In electronic devices that utilize a riser card, a riser cage bracket may be used to provide support to the riser card and to the expansion card coupled thereto, and fasteners may be used to couple the riser cage bracket to the electronic device. Accordingly, the riser cage bracket coupled to the electronic device can secure and support the expansion card when the expansion card is disposed in the riser cage bracket and detachably connected to the riser card.

### BRIEF DESCRIPTION OF THE DRAWINGS

Various examples will be described below with reference to the following figures.

FIG. 1A illustrates a block diagram of a portion of an electronic device including a chassis, a primary system board, a receptacle, and a riser cage assembly having a riser cage bracket and a fastener assembly in a first state according to an example of the present disclosure.

FIG. 1B illustrates a block diagram of the riser cage assembly of FIG. 1A, having the fastener assembly in a second state according to an example of the present disclosure.

FIG. 2 illustrates a perspective view of a portion of an electronic device including a receptacle and a riser cage assembly having a riser cage bracket and a fastener assembly according to an example of the present disclosure.

FIG. 3A illustrates a perspective view of an enclosure of the fastener assembly of FIG. 2 according to an example of the present disclosure.

FIG. 3B illustrates a perspective view of an actuator of the fastener assembly of FIG. 2 according to an example of the present disclosure.

FIG. 3C illustrates a perspective view of a shaft of the fastener assembly of FIG. 2 according to an example of the present disclosure.

FIG. 3D illustrates a perspective view of a biasing element of the fastener assembly of FIG. 2 according to an example of the present disclosure.

FIG. 3E illustrates a perspective view of a cover of the fastener assembly of FIG. 2 according to an example of the present disclosure.

FIGS. 4A-4B illustrate the fastener assembly of FIG. 2 in a first state according to an example of the present disclosure.

FIGS. 5A-5C illustrate a plurality of steps to transition the fastener assembly of FIGS. 4A-4B from the first state to a second state to fasten the riser cage assembly to the receptacle according to an example of the present disclosure.

FIGS. 6A-6B illustrate the fastener assembly of FIGS. 5A-5C in the second state according to an example of the present disclosure.

FIG. 7A-7C illustrate a plurality of steps to transition the fastener assembly of FIG. 6A-6B from the second state to the first state to release the riser cage assembly from the receptacle according to an example of the present disclosure.

FIG. 8A-8B illustrates the fastener assembly of FIG. 7A-7C in the second state according to an example of the present disclosure.

FIG. 9 is a flowchart depicting a method of removably fastening a riser cage assembly to an electronic device using a fastener assembly according to an example of the present disclosure.

### DETAILED DESCRIPTION

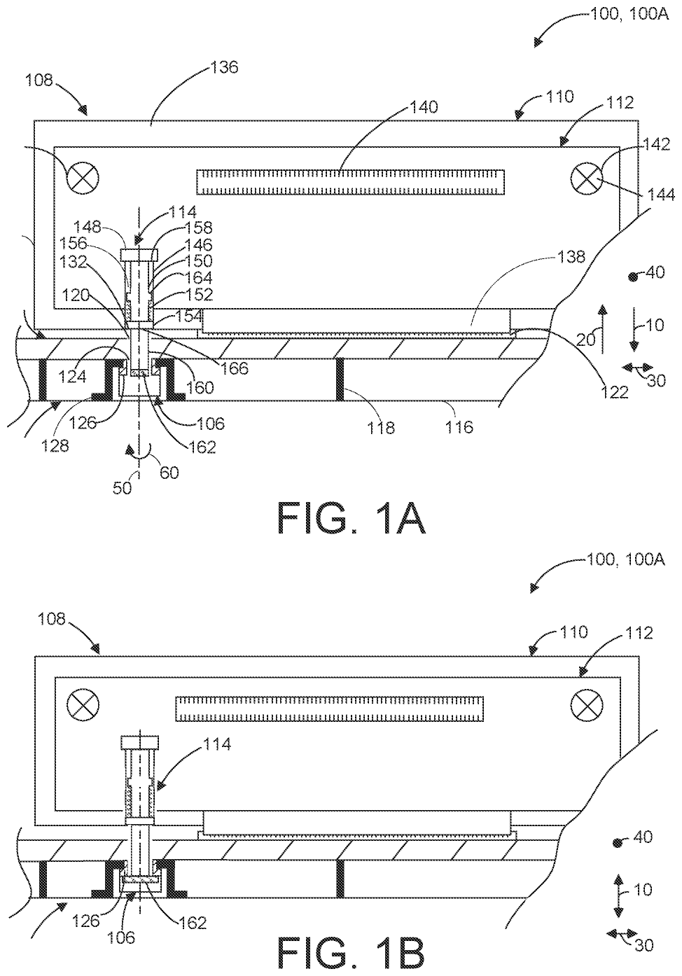

The following detailed description refers to the accompanying drawings. For purposes of explanation, certain examples are described with reference to the components illustrated in FIGS. 1-9. The functionality of the illustrated components may overlap, however, and may be present in a fewer or greater number of elements and components. Moreover, the disclosed examples may be implemented in various environments and are not limited to the illustrated examples. Wherever possible, the same reference numbers are used in the drawings and the following description to refer to the same or similar parts. It is to be expressly understood, however, that the drawings are for the purpose of illustration and description only. While several examples are described in this document, modifications, adaptations, and other implementations are possible. Accordingly, the following detailed description does not limit the disclosed examples. Instead, the proper scope of the disclosed examples may be defined by the appended claims.

As used herein, “riser card” refers to an electronic component configured to serve as an intermediary or adapter that electrically connects two other electronic components together, with the riser card having a circuit board and two connectors: a first connector configured to be coupled to a first electronic component of the electronic device such as a primary system board (e.g., motherboard), and a second connector configured to removably receive a corresponding connector of a second electronic component, e.g., an expansion card. As used herein, “riser cage bracket” refers to a supporting element connected to the riser card and configured to be physically coupled to the electronic device to support and physically secure the riser card in the electronic device (and in some cases, to physically support and secure the expansion card, when one is installed). As used herein, “riser cage assembly” may refer to an assembly of components such as a riser card, a riser cage bracket, and a fastener.

A riser cage assembly may be installed in an electronic device to allow the inclusion of additional electronic components such as an expansion card (e.g., display card, graphics processing unit (GPU), accelerator module, networking interface module (NIC), or the like) in the electronic device, and thereby improve performance or expand the functionality of the electronic device. For example, a riser card and fasteners (e.g., screws) are first coupled to the riser cage bracket to form a riser cage assembly, and the riser cage bracket is later coupled to a chassis of the electronic device via the fasteners such that the riser card is electrically connected to a primary system board of the electronic device. An expansion card is further installed in the riser cage bracket which may additionally secure and support the expansion card and electrically connect the expansion card to the primary system board via the riser card.

The chassis generally has space constraints either due to the density of the electronic components or due to size constraints imposed by a rack (or a cabinet) to accommodate the chassis within the rack. For example, certain electronic components such as power supply devices, storage drives, PCIe drives, or the like are disposed adjacent to each other and coupled to the chassis. Hence, such electronic components generally occupy substantial space in the chassis, thereby providing a limited space to dispose and couple certain other electronic components, such as a riser cage assembly in the chassis. Accordingly, after the riser cage assembly is installed in the chassis, due to the limited space in the chassis, coupling the riser cage bracket to the chassis may be extremely difficult. In particular, due to space constraints in the chassis, appropriate tools e.g., a screwdriver or the like cannot easily reach the location of the screws for fastening the riser cage bracket to the chassis or releasing the riser cage bracket from the chassis. Further, whenever an installation, maintenance, or replacement activity of the riser cage assembly is planned in the electronic device, a user may handily require the screwdriver to unfasten the screws and release the riser cage bracket from the chassis or fasten the screws and couple the riser cage bracket to the chassis. Therefore, performing any of the installation, maintenance, or replacement activities of the riser cage assembly in the electronic device may become extremely time-consuming and laborious.

A technical solution to the aforementioned problems may include providing a fastener assembly that can be operable without tools to removably fasten a riser cage assembly to an electronic device or release the riser cage assembly from the electronic device. In other words, the fastener assembly may be a tool-less instrument, which in an installed state of the riser cage assembly in the electronic device can be operated merely by an application of a force to either fasten the riser cage bracket to the electronic device or release the riser cage bracket from the electronic device. More specifically, the fastener assembly may include an actuator that may be pushed (e.g., by the application of the force) to drive a shaft of the fastener assembly and cause the shaft to rotate relative to a vertical axis, thereby allowing a locking arm of the shaft to i) engage with a receptacle coupled to a chassis of the electronic device to fasten the riser cage bracket to the receptacle or ii) disengage from the receptacle to release the riser cage bracket from the receptacle. In particular, the fastener assembly may be pushed to i) transition from a first state (e.g., a disengaged state) to a second state (e.g., an engaged state) to fasten the riser cage bracket to the receptacle or ii) transition from the second state to the first state to release the riser cage bracket from the receptacle. In some examples, the shaft may rotate about 90 degrees (e.g., perform a quarter turn) when the actuator is pushed every time to transition the fastener assembly between the first and second states.

In one or more examples, the fastener assembly may include an enclosure, an actuator, a shaft, and a biasing element, which may all operate in conjunction to transition the fastener assembly between the first and second states. The enclosure may include a bore extending along a vertical axis, guide teeth disposed within the bore, and bays defined between the guide teeth. In such examples, each of the guide teeth may include a first vertical surface, a second vertical surface, and a ramped surface extending between the first and second vertical surfaces. The actuator may include drivers and may be movably coupled to a first end of the enclosure with the drivers being disposed within the bore. The shaft may include blades and a locking arm, where the blades may be disposed within the bore and the locking arm may protrude out of the bore beyond a second end of the enclosure. In one or more examples, the shaft may be translatable along and rotatable about the vertical axis relative to the enclosure. The biasing element may be configured to generate a biasing force urging the shaft towards the first end of the enclosure. In the first state of the fastener assembly, the shaft may be at a first rotational orientation and the blades may be disposed within a first subset of the bays and abutting the first vertical surfaces of a first subset of the guide teeth. Similarly, in the second state of the fastener assembly, the shaft may be at a second rotational orientation and the blades may be disposed within a second subset of the bays and abutting the first vertical surfaces of a second subset of the guide teeth.

In some examples, the fastener assembly may further include a cover having an opening, coupled to the second end of the enclosure. In such examples, the locking arm of the shaft may extend beyond the second end of the enclosure via the opening in the cover. Similarly, the shaft may further include a flange disposed above the locking arm. In such examples, the biasing element is disposed around the shaft contacting the cover and the flange. Accordingly, the biasing element may be either compressed or expanded between the cover and the flange when the shaft is pushed by the actuator along a first direction or when the biasing element is relaxed to push the actuator back along a second direction by the shaft. In certain examples, the biasing element may be a spring.

During operation, the fastener assembly can be transitioned from the first state to the second state to removably fasten (e.g., couple) the riser cage bracket to the receptacle of the electronic device. For example: the actuator may be pushed along a first direction such that the drivers may push the blades in the first direction and compress the biasing element until the blades pass below the first vertical surfaces of the first subset of the guide teeth. In such cases, the drivers and the biasing force may cause the blades to move into the second subset of the bays. After the blades enter the second subset of the bays, the biasing element may push the shaft along a second direction opposite to the first direction such that the blades slide along the ramped surfaces of the first subset of the guide teeth until the blades abut the first vertical surfaces of the second subset of the guide teeth. In such examples, the sliding of the blades along the ramped surfaces may cause rotation of the shaft from the first rotational orientation to the second rotational orientation, thereby allowing the locking arm to engage with the receptacle and couple the riser cage assembly to the electronic device. In some examples, the locking arm includes a first set of protrusions. In such examples, in the installed state of the riser cage assembly in the electronic device, the opening is aligned with a mounting hole of the riser cage bracket to allow the locking arm to protrude into the receptacle via the opening and the mounting hole, and the first set of protrusions to engage with a second set of protrusions of the receptacle in the second state of the fastener assembly, to removably fasten the riser cage bracket to the electronic device.

Similarly, the fastener assembly can be further transitioned from the second state to the first state to release the riser cage bracket from the receptacle of the electronic device. For example, the actuator may be pushed once again along the first direction such that the drivers may push the blades in the first direction and compress the biasing element until the blades pass below the first vertical surfaces of the second subset of the guide teeth. In such cases, the drivers and the biasing force may cause the blades to move into the first subset of the bays. After the blades enter the first subset of the bays, the biasing element may push the shaft along the second direction such that the blades slide along the ramped surfaces of the second subset of the guide teeth until the blades abut the first vertical surfaces of the first subset of the guide teeth. In such examples, the sliding of the blades along the ramped surfaces may cause rotation of the shaft from the second rotational orientation to the first rotational orientation, thereby allowing the locking arm to disengage from the receptacle and release the riser cage assembly from the electronic device.

Since the fastener assembly can be transitioned between the first and second states merely by the application of the force, there is no requirement for separate tools to fasten the riser cage assembly to the electronic device or release the riser cage assembly from the electronic device. Further, the riser cage assembly may be easily deployed in the chassis of the electronic device having space constraints as only the application of the force is all it requires on the fastener assembly to fasten the riser cage assembly to the electronic device or release the riser cage assembly from the electronic device. Accordingly, performing the maintenance or replacement activities of the riser cage assembly may not be a time-consuming and laborious activity, as it was previously while using the screws and the screwdriver to fasten the riser cage assembly to the electronic device or release the riser cage assembly from the electronic device.

Referring to the Figures, FIG. 1A depicts a block diagram of a portion of an electronic device 100 having a fastener assembly 114 in a first state. FIG. 1B depicts a block diagram of the portion of the electronic device 100 having the fastener assembly 114 in a second state. It should be understood that FIGS. 1A-1B are not intended to illustrate specific shapes, dimensions, or other structural details accurately or to scale, and implementations of the electronic device 100 may have different numbers and arrangements of the illustrated components and may also include other parts that are not illustrated. In the description hereinafter, FIGS. 1A and 1B are described concurrently for ease of illustration.

The electronic device 100 may be a computer (e.g., a server, a storage device), a networking device (e.g., a switch, access point), or the like. In the example of FIGS. 1A-1B, the electronic device 100 is a computer 100A. In one or more examples, the electronic device 100 includes a chassis 102, a primary system board 104, a receptacle 106, and a riser cage assembly 108.

The chassis 102 may be configured to support various electronic components of the electronic device 100. Additionally, the chassis 102 may be configured to mount the electronic device 100 to a rack (or cabinet, not shown) of a data center (not shown). The chassis 102 may include a base 116 and a plurality of spacers 118 disposed spaced apart from each other and coupled to the base 116.

The primary system board 104 may be a motherboard of the electronic device 100. The primary system board 104 may include a through hole 120 and a connector 122. In some examples, the primary system board 104 is disposed on and coupled to the base 116 via the plurality of spacers 118 and one or more support elements 128.

The receptacle 106 includes an aperture 124 and a set of protrusions (e.g., a second set of protrusions 126). In some examples, the second set of protrusions 126 may be oriented along a direction (e.g., a third direction 30). The receptacle 106 is disposed on and coupled to the chassis 102 via the one or more support elements 128. In some examples, the receptacle 106 is positioned between the base 116 and the primary system board 104 such that the aperture 124 in the receptacle 106 is aligned with the through hole 120 of the primary system board 104.

The riser cage assembly 108 includes a riser cage bracket 110, a riser card 112, and the fastener assembly 114. In one or more examples, the riser cage assembly 108 may provide support to the riser card 112 and expansion card (not shown) and allow the expansion card to be installed to the primary system board 104 via the riser card 112.

The riser cage bracket 110 is the main structural support component of the riser cage assembly 108. The riser cage bracket 110 includes a riser body 130 and a riser window (not shown) coupled to each other to define a space therebetween to allow installation of the expansion card to the riser cage bracket 110. In particular, the riser body 130 is configured to provide support to the riser card 112 and the riser window is configured to provide support to the expansion card. In some examples, the riser body 130 includes a mounting hole 132 that is aligned with the through hole 120 of the primary system board 104, and a plurality of first riser holes 134.

The riser card 112 may be an electronic card of the electronic device 100. In one or more examples, the riser card 112 may include a circuit board 136, a first connector 138, a second connector 140, a plurality of second riser holes 142, and a plurality of fasteners 144. The first connector 138 is coupled to one end of the circuit board 136. The second connector 140 is coupled to a body (not labeled) of the circuit board 136. The second connector 140 may be configured to detachably connect to an electrical connector (not shown) of the expansion card. The plurality of second riser holes 142 may be disposed proximate to a plurality of peripheral sides of the circuit board 136 such that that the plurality of second riser holes 142 is aligned to the plurality of first riser holes 134 of the riser body 130 to allow the riser card 112 to be removably coupled to the riser cage bracket 110. In some examples, the riser card 112 is first disposed on the riser body 130 such that the plurality of second riser holes 142 is aligned with the plurality of first riser holes 134. Later, the fasteners 144 are fastened through the plurality of second riser holes 142, and the plurality of first riser holes 134 to removably couple the riser card 112 to the riser body 130. In such examples, the riser cage assembly 108 is further disposed on the electronic device 100 such that the first connector 138 of the riser card 112 is detachably connected to the connector 122 of the primary system board 104.

The fastener assembly 114 may be a coupling element configured to fasten the riser cage bracket 110 to the chassis 102 or release the riser cage bracket 110 from the chassis 102. In some examples, the fastener assembly 114 may include an enclosure 146, an actuator 148, a shaft 150, a biasing element 152, and a cover 154. The enclosure 146 may include a bore 156 extending along a vertical axis 60, guide teeth (not shown) within the bore 156, and bays (not shown) defined between the guide teeth. Each of the guide teeth may include a first vertical surface, a second vertical surface, and a ramped surface extending between the first and second vertical surfaces. Further, the actuator 148 may include a driver (not shown) and is movably coupled to a first end 158 of the enclosure 146 with the drivers being disposed within the bore 156. Further, the shaft 150 includes blades (not shown), a locking arm 160 having a first set of protrusions 162, and a flange 164 disposed above the locking arm 160. In some examples, the first set of protrusions 162 may be oriented along another direction (e.g., a fourth direction 40) which is perpendicular to the third direction 30. The blades may be disposed within the bore 156 and the locking arm 160 protrudes out of the bore 156 beyond a second end 166 of the enclosure 146. The shaft 150 may be configured to be driven by the driver of the actuator 148 to translate along and rotate about the vertical axis 60 relative to the enclosure 146. Further, the cover 154 having an opening (not labeled) is coupled to the second end 166 of the enclosure 146. The cover 154 allows the locking arm 160 to extend beyond the enclosure 146 via the opening. Further, the biasing element 152 is disposed around the shaft 150 contacting the cover 154 and the flange 164. The biasing element 152 is configured to generate a biasing force urging the shaft 150 towards the first end 158 of the enclosure 146.

The fastener assembly 114 may first protrude partially through the mounting hole 132 in the riser body 130 to couple with the riser cage bracket 110 and form the riser cage assembly 108. Later, the riser cage assembly 108 having the riser card 112, and the fastener assembly 114, may be installed in the electronic device 100 such that the fastener assembly 114 is partially protruded into the through hole 120 in the primary system board 104 and the opening in the receptacle 106. In such examples, when the riser cage assembly 108 is installed in the electronic device 100, the second set of protrusions 126 which is oriented perpendicular to the first set of protrusions 162 may not interfere with the first set of protrusions 162, thereby allowing the first set of protrusions 162 to protrude beyond the second set of protrusions 126.

In one or more examples, in an installed state of the riser cage assembly 108 in the electronic device 100, the fastener assembly 114 can be operated merely by an application of a force to either fasten the riser cage bracket 110 to the receptacle 106 or release the riser cage bracket 110 from the receptacle 106. For example, the fastener assembly 114 may be pushed along a first direction 10 to fasten the riser cage bracket 110 to the receptacle 106 or release the riser cage bracket 110 from the receptacle 106. In particular, referring to FIG. 1A, when the fastener assembly 114 is pushed along the first direction 10, the actuator 148 may push the shaft 150 to move along the first direction 10, and later the biasing element 152 may push the shaft 150 along a second direction 20 causing the actuator 148 and the enclosure 146 to guide the shaft 150 to rotate along a clockwise direction 50 about the vertical axis 60 relative to the enclosure 146 to transition the fastener assembly 114 from a first state (see, FIG. 1A) to a second state (see, FIG. 1B), thereby fastening the riser cage assembly 108 to the electronic device 100. In some examples, when the shaft 150 rotates relative to the vertical axis 60, the first set of protrusions 162 is disposed parallel to the second set of protrusions 126, thereby engaging the first set of protrusions 162 with the second set of protrusions 126 of the receptacle 106 and fastening the riser cage bracket 110 to the chassis 102. In other words, the shaft 150 causes the locking arm 160 to rotate and position the first set of protrusions 162 along the third direction 30 which is parallel to the second set of protrusions 126, thereby causing the first set of protrusions 162 to engage with the second set of protrusions 126. In some examples, the shaft 150 may rotate about 90 degrees, when the actuator 148 is pushed along the first direction 10.

Similarly, referring to FIG. 1B, when the fastener assembly 114 is pushed along the first direction 10, the actuator 148 may push the shaft 150 to move along the first direction 10, and later the biasing element 152 may push the shaft 150 along the second direction causing the actuator 148 and the enclosure 146 to guide the shaft 150 to rotate along the clockwise direction 50 about the vertical axis 60 to transition the fastener assembly 114 from the second state (see, FIG. 1B) to the first state (see, FIG. 1A), thereby releasing the riser cage assembly 108 from the electronic device 100. In some examples, when the shaft 150 rotates again relative to the vertical axis 60, the first set of protrusions 162 is disposed perpendicular to the second set of protrusions 126, thereby disengaging the first set of protrusions 162 of the locking arm 160 from the second set of protrusions 126 of the receptacle 106 and releasing the riser cage bracket 110 from the chassis 102. In other words, the shaft 150 causes the locking arm 160 to rotate again and position the first set of protrusions 162 along the fourth direction 40 which is perpendicular to the second set of protrusions 126, thereby causing the first set of protrusions 162 to disengage from the second set of protrusions 126. In some examples, the shaft 150 may rotate about 90 degrees again, when the actuator 148 is pushed along the first direction 10. The fastener assembly 114 and the process of translating the fastener assembly 114 between the first and second states are discussed in detail below.

Since the fastener assembly 114 can be transitioned between the first and second states merely by the application of the force, there is no requirement for separate tools to fasten the riser cage assembly 108 to the electronic device 100 or release the riser cage assembly 108 from the electronic device 100.

Further, the riser cage assembly 108 may be easily deployed in the chassis 102 having space constraints as only the application of the force is all it requires on the fastener assembly 114 to fasten the riser cage assembly 108 to the electronic device 100 or release the riser cage assembly 108 from the electronic device 100. Accordingly, performing the maintenance or replacement activities of the riser cage assembly 108 may not be a time-consuming and laborious activity, as it was previously while using screws and screwdriver to fasten a riser cage assembly to an electronic device or release the riser cage assembly from the electronic device.

Moreover, in addition to being easier to operate than tool-actuated fasteners, the fastener assembly 114 may also be easier to operate than other toolless fasteners, in some circumstances. In particular, in some electronic devices there may be little free space around the fastener assembly such that it is difficult for a user to manually manipulate a fastener, even if it is a toolless fastener. For example, fasteners that are actuated by manually twisting a knob, handle, or other similar structure may be difficult to actuate in devices in which there is little lateral free space around the fastener, as the user's fingers may be blocked from being positioning around the lateral sides of the knob or handle and therefore the user might not be able to obtain a solid grasp on the knob or handle. As another example, fasteners that are actuated by manually pivoting a lever or other similar structure vertically may be difficult to actuate in devices in which there is little lateral free space around the fastener, as the user might not be able to position their fingers under the lever handle to pull up the lever upward. In contrast, in some examples disclosed herein, the force needed to actuate the fastener assembly 114 may be applied even when there is little or no free space on the lateral sides of the fastener assembly. For example, the force may be applied by a user moving their finger along a vertical direction and pushing down on the top of actuator 148, and this maneuver can be performed relatively easily even in cases in which there is little free space around the fastener because the user does not need to position their fingers along any lateral side of, or below, any part of the fastener assembly 114. Accordingly, the fastener assembly 114 can be manually actuated easily even in electronic devices which have very tight space constraints in which other toolless fasteners might be difficult or impossible to manually actuate.

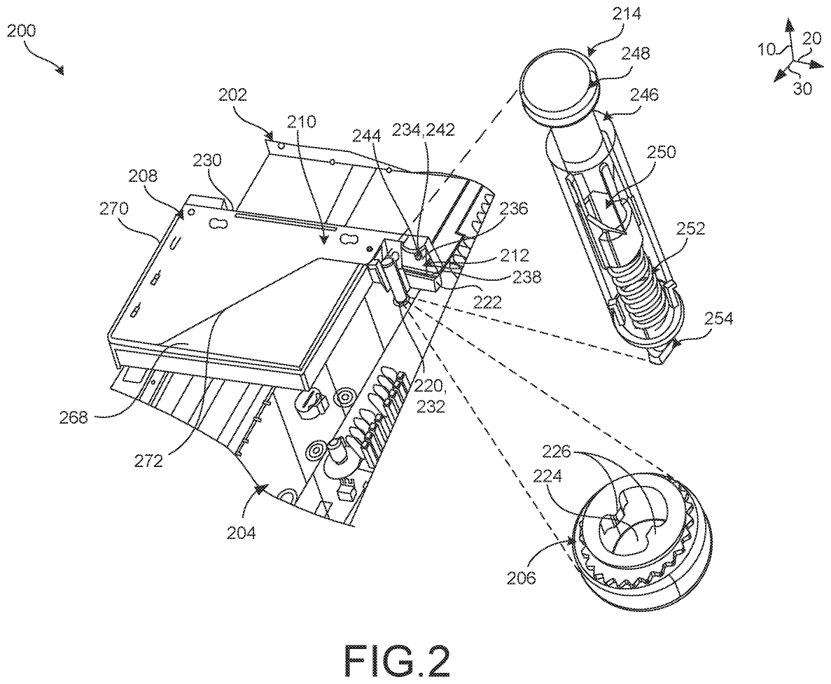

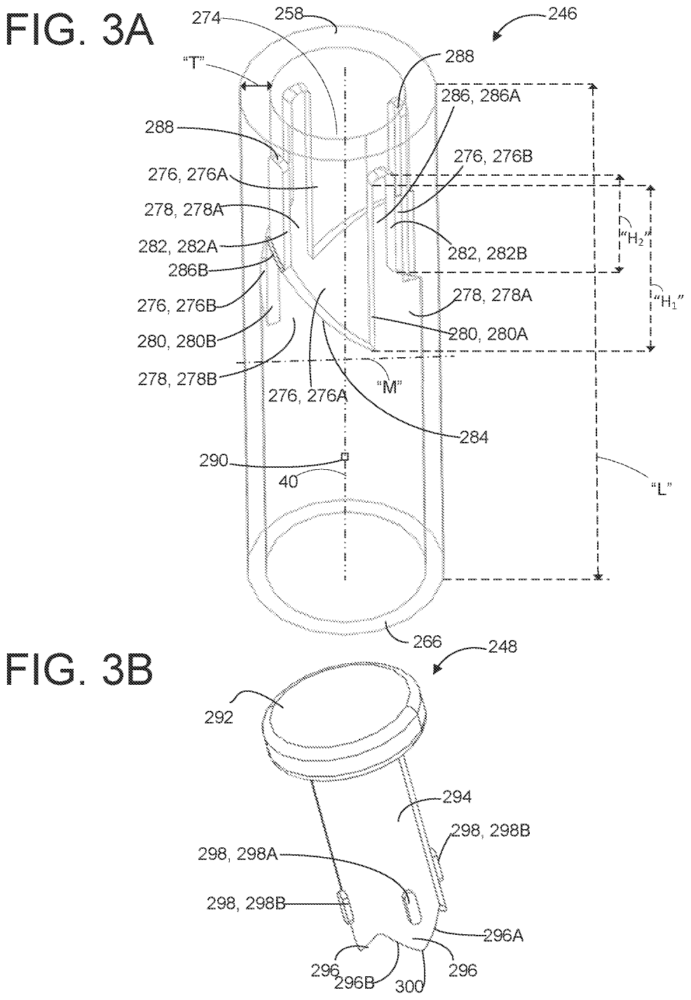

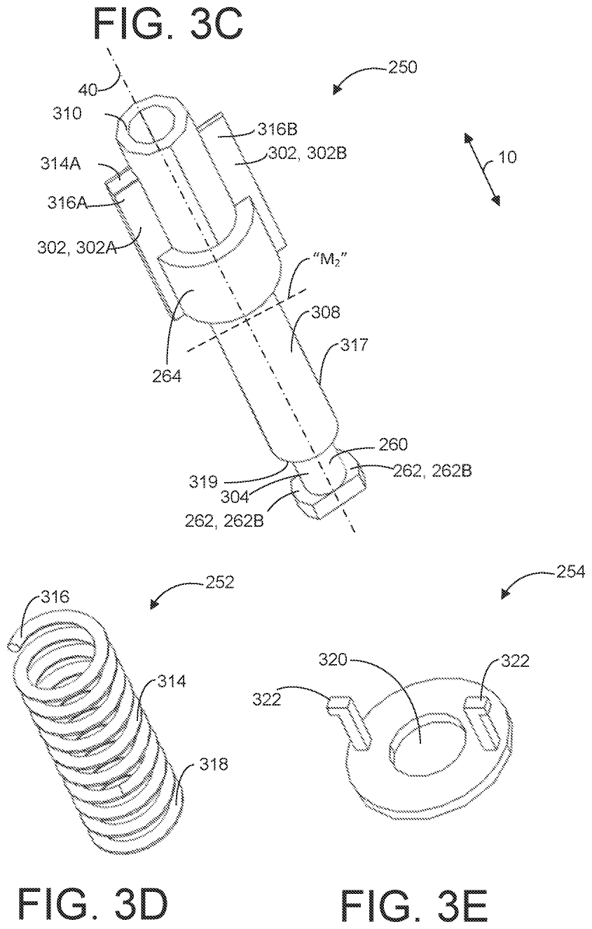

FIG. 2 depicts a perspective view of a portion of an electronic device 200 having a fastener assembly 214 in a first state. FIGS. 3A depicts a perspective view of an enclosure 246 of the fastener assembly 214; FIG. 3B depicts a perspective view of an actuator 248 of the fastener assembly 214; FIG. 3B depicts a perspective view of a shaft 250 of the fastener assembly 214; FIG. 3D depicts a perspective view of a biasing element 252 of the fastener assembly 214; and FIG. 3E depicts a perspective view of a cover 254 of the fastener assembly 214. In the description hereinafter, FIGS. 2 and 3A-3E are described concurrently for ease of illustration. In some examples, the electronic device 200 is a computer. As discussed herein the electronic device 200 includes a chassis 202, a primary system board 204, a receptacle 206, and a riser cage assembly 208.

The chassis 202 may be a sheet metal enclosure, which may be configured to support various electronic components of the electronic device 200 and mount the electronic device 200 to a rack (not shown) of a data center (not shown). The primary system board 204 may be a motherboard of the electronic device 200. In one or more examples, the primary system board 204 may include hardware components such as central processor units, resistors, capacitors, or the like (not shown) to provide some basic function to the electronic device 200. The primary system board 204 includes a through hole 220 and a connector 222 which is oriented along a first direction 10. In some examples, the primary system board 204 is disposed on and coupled to a base (not shown) of the chassis 202, as discussed in the example of FIGS. 1A-1B. The receptacle 206 is a circular receiver component having an aperture 224 and a set of protrusions (e.g., a second set of protrusions 226), which is oriented along a third direction 30. The receptacle 206 is disposed on and coupled to the chassis 202, as discussed in the example of FIGS. 1A-1B. In some examples, the receptacle 206 may be positioned between the base of the chassis 202 and the primary system board 204 such that the aperture 224 in the receptacle 206 is aligned with the through hole 220 of the primary system board 204.

The riser cage assembly 208 includes a riser cage bracket 210, a riser card 212, and the fastener assembly 214. In one or more examples, the riser cage assembly 208 provides support to the riser card 212 and an expansion card 268 and further allows the expansion card 268 to be electrically connected to the primary system board 204 via the riser card 212. In certain examples, the expansion card 268 may be a PCIe card, such as a display card, graphics processing unit (GPU), accelerator module, networking interface module (NIC), or the like).

The riser cage bracket 210 is a main structural support component of the riser cage assembly 208. The riser cage bracket 210 includes a riser body 230 and a riser window 270 coupled to each other to define a space 272 therebetween which allows the installation of the expansion card 268 in the riser cage bracket 210. In some examples, the riser body 230 includes a mounting hole 232 that is aligned with the through hole 220 of the primary system board 204, and a plurality of first riser holes 234. In such examples, the riser body 230 may provide support to the riser card 212.

The riser card 212 is an electronic card including a circuit board 236, a first connector 238, a second connector (not shown), a plurality of second riser holes 242, and a plurality of fasteners 244. The plurality of second riser holes 242 may be disposed proximate to a plurality of peripheral sides of the circuit board 236 such that that the plurality of second riser holes 242 is aligned to the plurality of first riser holes 234 of the riser body 230 to allow the riser card 212 to be removably coupled to the riser cage bracket 210. The first connector 238 of the riser card 212 is oriented along the first direction 10 and coupled to one end of the circuit board 236 when the riser card 212 is removably coupled to the riser cage bracket 210. The second connector of the riser card 212 may be oriented along a third direction 30 and coupled to a body (not labeled) of the circuit board 236. The second connector of the riser card 212 may be configured to detachably connect to an electrical connector (not shown) of the expansion card 268 when the expansion card 268 is installed in the riser cage bracket 210 such that the expansion card 268 is electrically connected to the primary system board 204 via the riser card 212. In such examples, the riser window 270 may support the expansion card 268 when it is installed in the space 272 defined in the riser cage bracket 210.

The fastener assembly 214 may be a coupling element configured to fasten the riser cage bracket 210 to the chassis 202 or release the riser cage bracket 210 from the chassis 202. In some examples, the fastener assembly 214 may include an enclosure 246, an actuator 248, a shaft 250, a biasing element 252, and a cover 254.

Referring to FIG. 3A, the enclosure 246 is a hollow cylindrical component having a thickness “T” and a length “L”. It may be noted herein that the enclosure 246 in FIG. 3A is shown to be transparent to depict various interior features of the enclosure 246 and such an illustration of the enclosure 246 should not be construed as a limitation of the present disclosure. The enclosure 246 has a first end 258, a second end 266, and a bore 274 extending along a vertical axis 60 between the first end 258 and the second end 266. The enclosure 246 further includes guide teeth 276 within the bore 274 and bays 278 defined between the guide teeth 276. The guide teeth 276 and the bays 278 are formed by etching some portions of the thickness “T” from an inner surface (not labeled) of the enclosure 246 such that an outer surface (not labeled) of the enclosure 246 remains to have a planar geometry. Accordingly, the guide teeth 276 and the bays 278 are defined within the thickness “T” of the enclosure 246 from the inner surface of the enclosure 246. In some examples, the guide teeth 276 and the bays 278 are located between the first end 258 and a mid-plane “M” of the enclosure 246. Further, each of the guide teeth 276 includes a first vertical surface 280, a second vertical surface 282, and a ramped surface 284 extending between the first and second vertical surfaces 280, 282. For example, each of the first and second vertical surfaces 280, 282 has a planar surface, and the ramped surface 284 has a curved surface. In such examples, the first vertical surface 280 has a first height, “H1” and the second vertical surface 282 has a second height “H2” smaller than the first height “H1”. Accordingly, the ramped surface 284 extending between the first and second vertical surfaces 280, 282 has the curved surface, which is inclined at an angle of about “135” degrees.

In the example of FIG. 3A, the enclosure 246 includes four guide teeth 276. In such examples, each of two mutually opposite guide teeth 276 may form a subset of the guide teeth. Thus, the enclosure 246 has a first subset of the guide teeth 276A and a second subset of the guide teeth 276B. Similarly, the enclosure 246 includes four bays 278. In such examples, each of two mutually opposite bays 278 may form a subset of bays 278. Thus, the enclosure 246 has a first subset of bays 278A and a second subset of bays 278B. Each of the bays 278 has a vertical groove 286 defined between the first vertical surface 280 of one of the guide teeth 276 and the second vertical surface 282 of another adjacent guide teeth 276. In such examples, the enclosure 246 further includes blockers 288 disposed within vertical grooves 286A of the second subset of the bays 278B. The enclosure 246 further includes a pair of through-holes 290 disposed between the second end 266 and the mid-plane “M” and extending along the thickness “T” between the inner and outer surfaces of the enclosure 246. The pair of through-holes 290 may allow the cover 254 to couple to the enclosure 246.

Turning to FIG. 3B, the actuator 248 includes a head portion 292 and a body portion 294. The head portion 292 has a diameter greater than a diameter of the body portion 294 and the bore 274 of the enclosure 246. The diameter of the body portion 294 of the actuator 248 is substantially equal to the diameter of the bore 274 so as to allow the body portion 294 to movably couple to the first end 258 of the enclosure 246. The body portion 294 has drivers 296 defined at its end portion and guides 298 defined on its outer surface (not labeled). In some examples, each of the drivers 296 has a “V” shaped profile defined by an endpoint 300, a sloped surface 296A extending from the endpoint 300 at an angle of about 45 degrees, and a first sloped surface 296B extending from the endpoint 300 at an angle of about 135 degrees. Each guide 298 has a width substantially equal to a width of the vertical groove 286 of the enclosure 246. In the examples of FIG. 3B, the body portion 294 includes four drivers 296 and four guides 298 e.g., a first set of guides 298A and a second set of guides 298B.

Referring to FIG. 3C, the shaft 250 includes blades 302, a locking arm 260, and a flange 264. The blades 302 has a planar shape extending along a first direction 10 from an outer surface 308 of a body 317 of the shaft 250. In the example of FIG. 3B. the shaft 250 includes two blades, e.g., a first blade 302A and a second blade 302B. Each blade 302 has a first end portion (not labeled) located proximate to a first end 310 of the body 317 of the shaft 250 and a second end portion (not labeled) located proximate to a mid-plane “M2” of the body 317 of the shaft 250. In such examples, the first end portion of each blade 302 has a second sloped surface 314A. In particular, the second sloped surface 314A is formed on a first surface 316A of a corresponding blade 302. In some examples, the first sloped surface 296B of a corresponding driver 296, the second sloped surface 314A of the corresponding blade 302, and the ramped surface 284 of the enclosure 246 are complementary surfaces. The locking arm 260 extends from a second end 319 of the body 317 of the shaft 250. The locking arm 260 includes a first set of protrusions 262 (e.g., first protrusions 262A, 262B), each extending from an outer surface 304 of the locking arm 260. In some examples, the two first protrusions 262A, 262B are positioned opposite to each other at an end portion of the locking arm 260. The flange 264 is disposed above the locking arm 260 and is connected to the blades 302. The flange 264 has a diameter greater than the body 317 of the shaft 250. The width of the shaft 250 is smaller than the diameter of the bore 274 of the enclosure 246, thereby allowing the shaft 250 to move along the vertical axis 60 and rotate about the vertical axis 60 relative to the enclosure 246.

Turning to FIG. 3D, the biasing element 252 is a spring, for example, a compression spring. In some other examples, the biasing element 252 may be a bellow or the like, without deviating from the scope of the present disclosure. The biasing element 252 has a wire 314, which is wrapped in a coil shape that resembles a screw thread. The biasing element 252 has ends portions, for example, a first end 316 and a second end 318 disposed in a mutually opposite direction. The biasing element 252 may be designed to carry, pull, or push loads.

Referring to FIG. 3E, the cover 254 is a circular component having an opening 320 and a pair of snapping arms 322. The opening 320 is disposed at a center of the cover 254 and configured to allow the locking arm 260 to protrude through the cover 254. The pair of snapping arms 322 are disposed to an outer perimeter of the cover 254 and configured to engage with the pair of through-holes 290 of the enclosure 246.

The fastener assembly 214 is assembled by first movably coupling the body portion 294 of the actuator 248 to the first end 258 of the enclosure 246 such that the drivers 296 are disposed within the bore 274 of the enclosure 246, each of the guides 298 is slidably disposed in a corresponding first vertical groove 286 of the bays 278, and the head portion 292 is located outside the first end 258 of the enclosure 246. In particular, each guide of the first set of guides 298A is disposed in a corresponding vertical groove of the first set of vertical grooves 286A, and each guide of the second set of guides 298A is disposed in a corresponding vertical groove of the second set of vertical grooves 286B. Further, the body 317 of the shaft 250 is disposed from the second end 266 of the enclosure 246 such that the blades 302 are disposed within the bore 274 and the locking arm 260 protrudes out of the bore 274 beyond the second end 266 of the enclosure 246. In particular, each of the blades 302 is disposed in the first set of bays 278A contacting a corresponding first vertical surface of the first set of guide teeth 276A. Later, the biasing element 252 is disposed around the shaft 250 from the second end 266 of the enclosure 246 such that the first end 316 of the biasing element 252 contacts the flange 264 of the shaft 250. Finally, the cover 254 is disposed from the second end 266 of the enclosure 246 such that the second end 318 of the biasing element 252 contacts the cover 245, the locking arm 260 protrudes through the opening 320, and the pair of snapping arms 322 engages with the pair of through-holes 290 of the enclosure 246 so as to retain the cover 254 to the enclosure 246, and thereby complete the assembly of the fastener assembly 214, as shown in FIG. 2. In some examples, as the cover 254 is disposed at the second end 266 of the enclosure 246, the cover 254 pushes the biasing element 252 and the shaft 250 towards the first end 258 of the enclosure 246, thereby causing a portion of each of the blades 302 to extend into the vertical groove 286A of the first subset of the bays 278A and contact the first set of guides 298A. In the example of FIG. 2, the fastener assembly 214 is in a first state. It may be noted herein that the term “first state” may refer to a condition of the fastener assembly 214, where the shaft 250 is at a first rotational orientation and the blades 302 are disposed within the first subset of the bays 278A and abutting the first vertical surfaces 280A of the first subset of the guide teeth 276A. In other words, in the first state, the fastener assembly 214 may release the riser cage bracket 210 from the receptacle 206. Accordingly, in the first state, rotation of the shaft 250 in any direction is prevented by the blades 302 being within the vertical grooves 286A of the first subset of the bays 278A. In one or more examples, the shaft 250 is translatable along and rotatable about the vertical axis 60 relative to the enclosure 246 to transition from the first state (e.g., release state) to a second state (fastened state). It may be noted herein that the term “second state” may refer to another condition of the fastener assembly 214, where the shaft 250 is at a second rotational orientation and the blades 302 are disposed within the second subset of the bays 278B and abutting the first vertical surfaces 280B of the second subset of the guide teeth 276B. In other words, in the second state, the fastener assembly 214 may fasten the riser cage bracket 210 to the receptacle 206. In one or more examples, the shaft 250 may rotate about 90 degrees clockwise to transition the fastener assembly 214 between the first state and the second state.

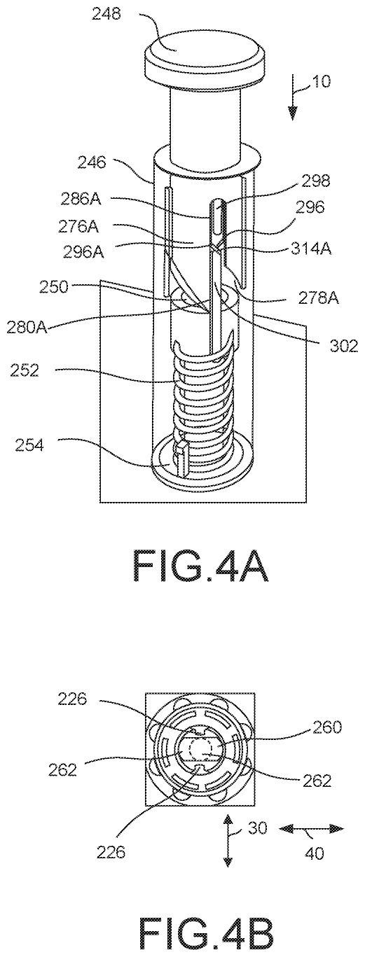

Referring back to FIG. 2, the receptacle 206 is disposed below the primary system board 204 and coupled to the chassis 202 of the electronic device 200 such that the aperture 224 of the receptacle 206 is aligned to the opening 320 of the through hole 220 in the primary system board 204. Further, the riser card 212 is disposed on the riser body 230 such that the plurality of second riser holes 242 is aligned with the plurality of first riser holes 234. The fasteners 244 are fastened through the plurality of second riser holes 242, and the plurality of first riser holes 234 to removably couple the riser card 212 to the riser body 230. Later, the fastener assembly 214 is coupled to the riser cage bracket 210 to form the riser cage assembly 208. In particular, the fastener assembly 114 may protrude partially through the mounting hole 232 in the riser body 230 to couple with the riser cage bracket 210 and form the riser cage assembly 208. Later, the riser cage assembly 208 having the riser card 212, and the fastener assembly 214, is installed in the electronic device 200 such that the fastener assembly 214 partially protrudes into the opening 320 in the receptacle 206, the through hole 220 in the primary system board 204, and the aperture 224 in the receptacle 206. In such examples, when the riser cage assembly 208 is installed in the electronic device 200, the second set of protrusions 226 of the receptacle 206 which is oriented perpendicular to the first set of protrusions 262 of the locking arm 260 may not interfere with each other, thereby allowing the first set of protrusions 262 to protrude beyond the second set of protrusions 226. Further, the riser cage assembly 208 installed in the electronic device 200 may be removably coupled to the electronic device 200 by the fastener assembly 214, as discussed herein below in the examples of FIGS. 4A-4B, 5A-5C and 6A-6B.

After the riser cage assembly 208 is fastened (e.g., removably coupled) to the chassis 202, the expansion card 268 may be disposed in the space 272 defined by the riser cage bracket 210 to install the expansion card 268 to the electronic device 200. In such examples, the riser window 270 of the riser cage bracket 210 may include mounting features that engage with complementary engagement features of the expansion card 268 to removably couple the expansion card 268 to the riser window 270. Further, when the expansion card 268 is installed in the riser cage bracket 210, the electrical connector of the expansion card 268 may be connected to the second connector of the riser card 212, thereby electrically connecting the expansion card 268 to the primary system board 204 via the riser card 212.

FIGS. 4A-4B depict a fastener assembly 214 of FIG. 2 in a first state. Referring to FIG. 4A in particular, in the installed state of the riser cage assembly 208 in the electronic device 200, the fastener assembly 214 is in the first state, where the shaft 250 is at a first rotational orientation and the blades 302 are disposed within the first subset of the bays 278A and abutting the first vertical surfaces 280A of the first subset of the guide teeth 276A. In such examples, the biasing element 252 causes the drivers 296 and the blades 302 to be disposed in contact with each other within the first vertical grooves 286A. In particular, the first sloped surface 296B of each of the drivers 296 in the first subset of the bays 278A is engaged with the second sloped surface 314A of the corresponding blade 302. Referring to FIG. 4B in particular, the second set of protrusions 226 of the receptacle 206 is oriented along a third direction 30, and the first set of protrusions 262 of the locking arm 260 is oriented along a fourth direction 40. In other words, the first and second sets of protrusions 262, 226 are oriented perpendicular to each other, thereby allowing the first set of protrusions 262 to protrude beyond the second set of protrusions 226. Hence, the first set of protrusions 262 of the locking arm 260 may not engage with the second set of protrusions 226 of the receptacle 206, thereby allowing the riser cage bracket 210 to be released from the receptacle 206. In such examples, the fastener assembly 214 may be operated merely by an application of a force to transition the fastener assembly 214 from the first state to the second state, thereby fastening the riser cage assembly 208 to the electronic device 200, as discussed herein below.

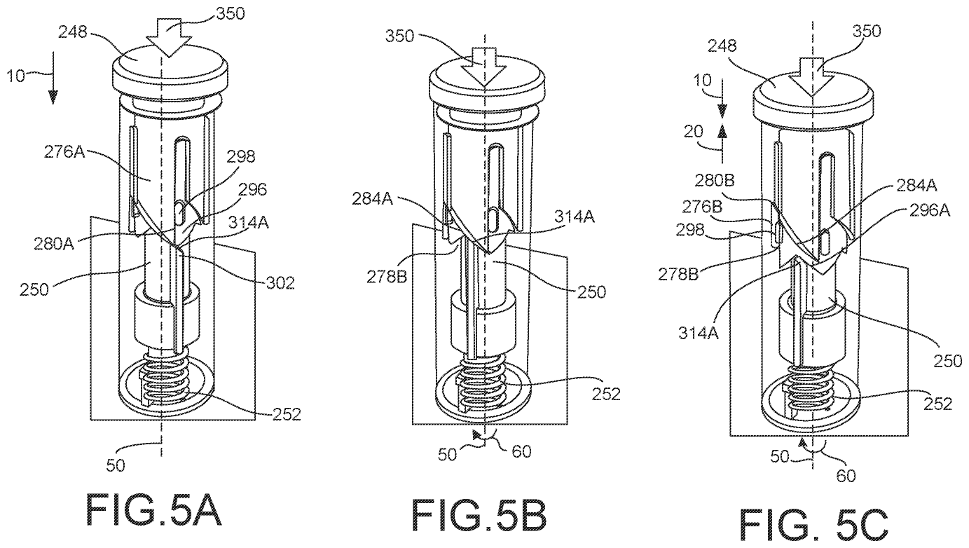

FIGS. 5A-5C depict a plurality of steps to transition the fastener assembly 214 of FIG. 4A-4B from the first state to a second state to fasten a riser cage assembly 208 to the receptacle 206 of the electronic device 200. Referring to FIG. 5A in particular, the actuator 248 may be pushed along the first direction 10 by an application of force 350 such that the drivers 296 slidably disposed in the first set of the bays 278A push the blades 302 in the first direction 10 and compress the biasing element 252 until the blades 302 pass below the first vertical surfaces 280A of the first subset of the guide teeth 276A. In particular, the drivers 296 pushes the blades 302 until the blades 302 passes below the first vertical surfaces 280A of the first subset of the guide teeth 276A.

Referring to FIG. 5B, as the blades 302 passes below the first vertical surfaces 280A of the first subset of the guide teeth 276A, the enclosure 246, the drivers 296, and the biasing element 252 cause the blades 302 to slide (move) into the second subset of the bays 278B. In particular, the ramped surfaces 284A of the enclosure 246, the first sloped surfaces 296B of the drivers 296, and the second sloped surfaces 314A of the blades 302 are engaged with each other in a manner that urges the shaft 250 to rotate about the vertical axis 60, and thereby slidably move into the second subset of the bays 278B.

Referring to FIG. 50, as the actuator 248 is further pushed along the first direction 10, the first sloped surfaces 296B of the drivers 296 and the second sloped surfaces 314A of the blades 302 cause the shaft 250 to continue rotating about the vertical axis 60 until the actuator 248 is stopped pushing along the first direction and the biasing element 252 starts expanding back to push back the actuator 248 along the second direction 20 opposite to the first direction 10, through the shaft 250.

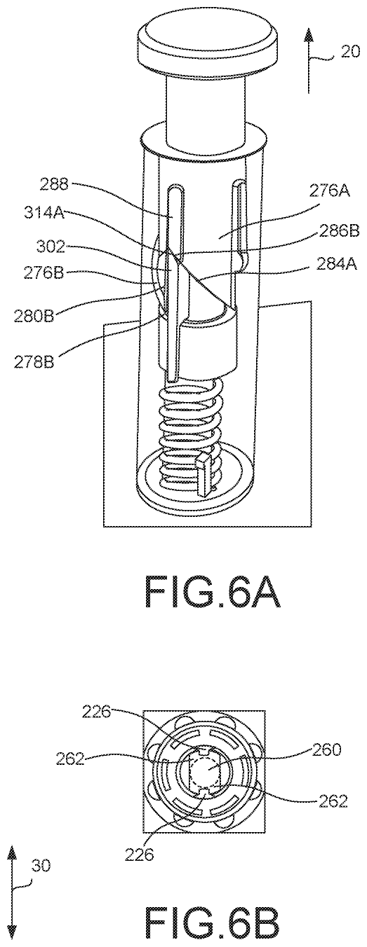

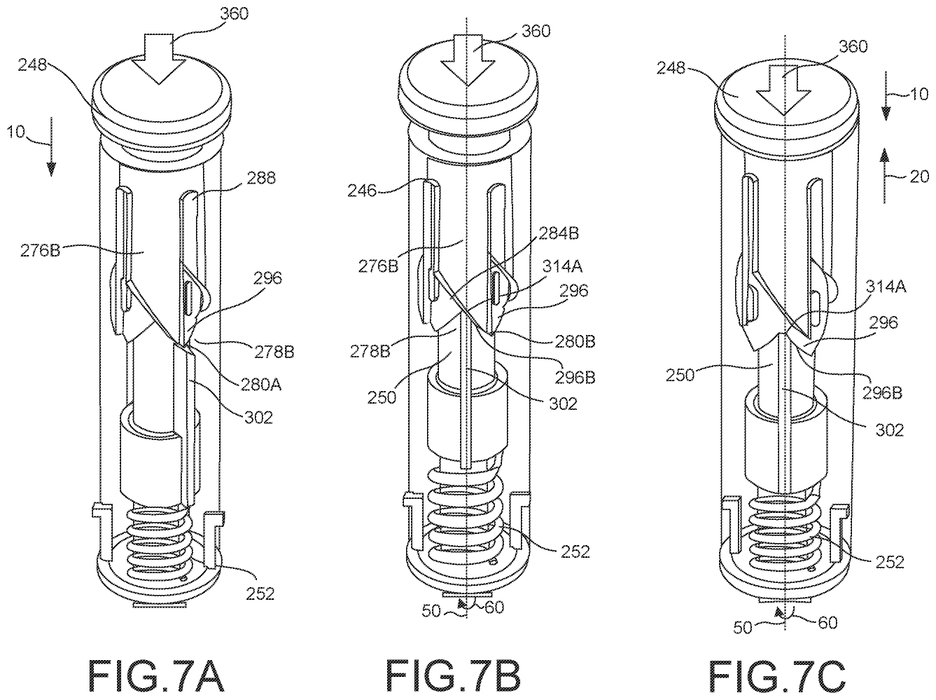

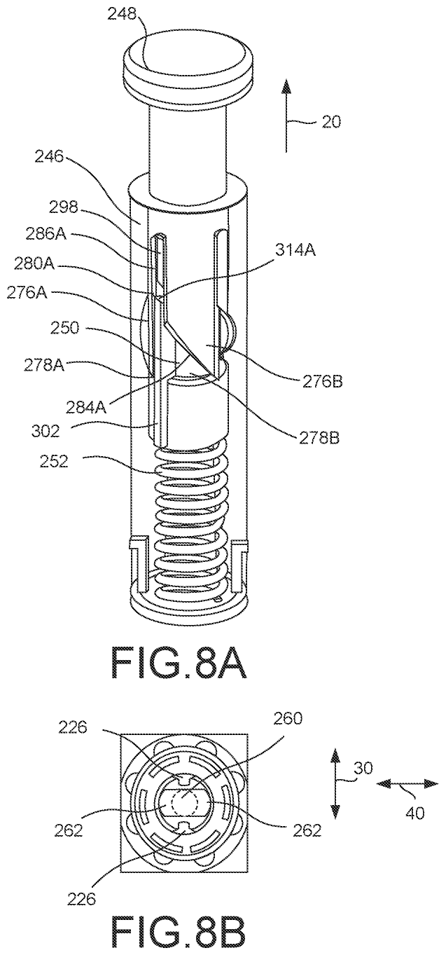

FIGS. 6A-6B depict the fastener assembly of FIGS. 5A-5C in the second state. Referring to FIG. 6A in particular, after the actuator 248 is stopped from pushing along the first direction 10, the biasing element 252 starts pushing back the actuator 248 along the second direction 20 through the shaft 250 such that the blades 302 further slidably move along the ramped surfaces 284A of the first subset of the guide teeth 276A until the blades 302 is abutted by the first vertical surfaces 280B of the second subset of the guide teeth 276B. In some examples, the blockers 288 are configured to block motion of the blades 302 within the vertical grooves 286B of the second subset of the bays 278B while not blocking the motion of the guides 298 (as shown in FIG. 5C) within the vertical grooves 286B of the second subset of the bays 278B, thereby locking the fastener assembly 214 in the second state. In other words, in the second state of the fastener assembly 214, the shaft 250 is at a second rotational orientation and the blades 302 are disposed within the second subset of the bays 278B and abutting the first vertical surfaces 280B of the second subset of the guide teeth 276B. Referring to FIG. 6B in particular, the second set of protrusions 226 of the receptacle 206 is oriented along a third direction 30, and the first set of protrusions 262 of the locking arm 260 is also oriented along the third direction 30. In other words, the first and second sets of protrusions 262, 226 are oriented parallel to each other, thereby engaging the first set of protrusions 262 with the second set of protrusions 226 of the receptacle 206 and fastening the riser cage bracket 210 to the receptacle 206. In such examples, the fastener assembly 214 may be operated again by the application of a force 360 along the first direction 10 to transition the fastener assembly 214 from the second state to the first state, thereby releasing the riser cage assembly 208 from the electronic device 200, as discussed herein below in the examples of FIGS. 7A-7C and 8A-8B.

FIGS. 7A-7C depict a plurality of steps to transition the fastener assembly 214 of FIG. 6A-6B from the second state to the first state to release the riser cage assembly 208 from the receptacle 206 of the electronic device 200. Referring to FIG. 7A in particular, the actuator 248 may be pushed again along the first direction 10 by an application of force 360 such that the drivers 296 slidably disposed in the second set of the bays 278B push the blades 302 in the first direction 10 and compress the biasing element 252 until the blades 302 pass below the first vertical surfaces 280B of the second subset of the guide teeth 276B. In particular, the drivers 296 pushes the blades 302 until the blades 302 passes below the first vertical surfaces 280B of the second subset of the guide teeth 276B.

Referring to FIG. 7B, as the blades 302 passes below the first vertical surfaces 280B of the second subset of the guide teeth 276B, the enclosure 246, the drivers 296, and the biasing element 252 cause the blades 302 to slide (move) into the first subset of the bays 278B. In particular, the ramped surfaces 284B of the enclosure 246, the first sloped surfaces 296B of the drivers 296, and the second sloped surfaces 314A of the blades 302 are engaged with each other in a manner that urges the shaft 250 to rotate about the vertical axis 60, and thereby slidably move into the first subset of the bays 278A.

Referring to FIG. 7C, as the actuator 248 is further pushed along the first direction 10, the first sloped surfaces 296B of the drivers 296 and the second sloped surfaces 314A of the blades 302 cause the shaft 250 to continue rotating about the vertical axis 60 until the actuator 248 is stopped pushing along the first direction 10 and the biasing element 252 starts expanding back to push back the actuator 248 along the second direction 20 opposite to the first direction 10, through the shaft 250.

FIGS. 8A-8B depict the fastener assembly of FIGS. 7A-7C in the first state. Referring to FIG. 8A in particular, after the actuator 248 is stopped from pushing along the first direction 10, the biasing element 252 starts pushing back the actuator 248 along the second direction 20 through the shaft 250 such that the blades 302 further slidably move along the ramped surfaces 284A of the second subset of the guide teeth 276B until the blades 302 is abutted by the first vertical surfaces 280A of the first subset of the guide teeth 276A. In some examples, the blades 302 and the guides 298 may be allowed to move within the vertical grooves 286A of the first subset of the bays 278A. Accordingly, in the first state of the fastener assembly 214, the shaft 250 is at the first rotational orientation and the blades 302 are disposed within the first subset of the bays 278A and abutting the first vertical surfaces 280A of the first subset of the guide teeth 276A. Referring to FIG. 8B in particular, the second set of protrusions 226 of the receptacle 206 is oriented along a third direction 30, and the first set of protrusions 262 of the locking arm 260 is oriented along a fourth direction 40. In other words, the first and second sets of protrusions 262, 226 are oriented perpendicular to each other, thereby disengaging the first set of protrusions 262 from the second set of protrusions 226 of the receptacle 206 and releasing the riser cage bracket 210 from the receptacle 206.

Since the fastener assembly 214 can be transitioned between the first and second states merely by the application of the force, there is no requirement for separate tools to fasten the riser cage assembly 208 to the electronic device 200 or release the riser cage assembly 208 from the electronic device 200. Further, the riser cage assembly 208 may be easily deployed in the chassis 202 having space constraints as only the application of the force is all it requires on the fastener assembly 214 to fasten the riser cage assembly 208 to the electronic device 200 or release the riser cage assembly 208 from the electronic device 200.

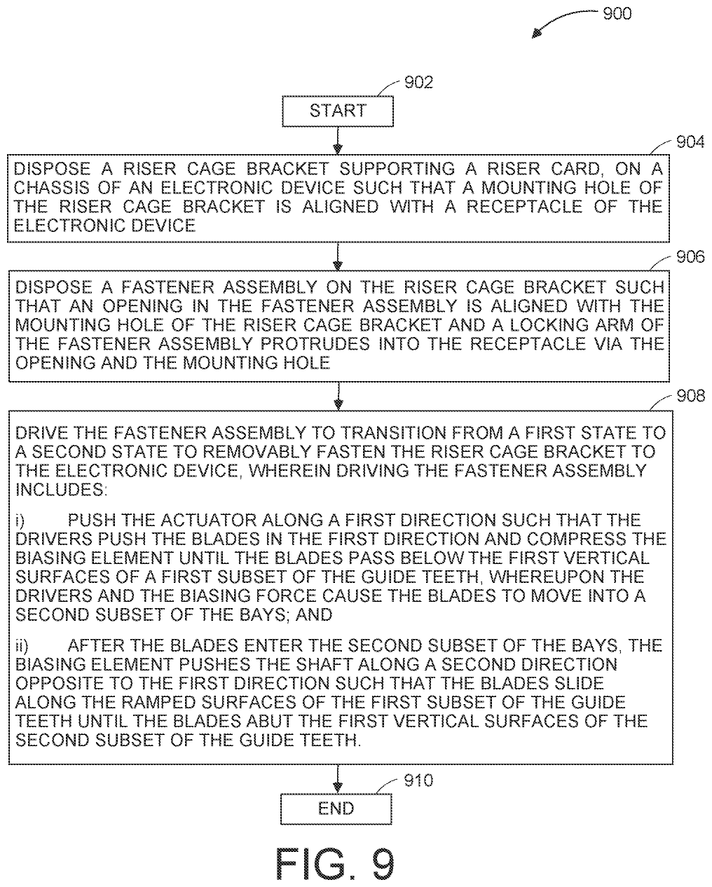

FIG. 9 depicts a flowchart showing a method 800 of removably fastening a riser cage bracket to an electronic device using a fastener assembly. It may be noted herein that the method 900 is described in conjunction with FIGS. 1A-1B, 2, and 3A-3E, for example. The method 900 starts at block 902 and continues to block 904.

At block 904, the method 900 includes disposing a riser cage bracket supporting a riser card, on a chassis of an electronic device such that a mounting hole of the riser cage bracket is aligned with a receptacle of the electronic device. The method 900 continues to block 906.

At block 906, the method 900 includes disposing a fastener assembly on the riser cage bracket such that an opening in the fastener assembly is aligned with the mounting hole of the riser cage bracket and a locking arm of the fastener assembly protrudes into the receptacle via the opening and the mounting hole. In some examples, the fastener assembly includes an enclosure, an actuator, a shaft, and a biasing element. The enclosure includes a bore extending along a vertical axis, guide teeth within the bore, and bays defined between the guide teeth, wherein each of the guide teeth includes a first vertical surface, a second vertical surface, and a ramped surface extending between the first and second vertical surface. The actuator includes drivers and is movably coupled to a first end of the enclosure with the drivers disposed within the bore. The shaft includes blades and the locking arm, wherein the blades are disposed within the bore and the locking arm protrudes out of the bore beyond a second end of the enclosure, wherein the shaft is translatable along and rotatable about the vertical axis relative to the enclosure. The biasing element is configured to generate a biasing force urging the shaft towards the first end of the enclosure. In one or more examples, each driver includes a first sloped surface, and each blade includes a second sloped surface, where the first sloped surface, the second sloped surface, and the ramped surface of each guide tooth are complementary surfaces. The method 900 continues to block 908.

At block 908, the method 900 further includes driving the fastener assembly to transition from a first state to a second state to removably fasten the riser cage bracket to the electronic device. In some examples, driving the fastener assembly includes: i) pushing the actuator along a first direction such that the drivers push the blades in the first direction and compress the biasing element until the blades pass below the first vertical surfaces of a first subset of the guide teeth, whereupon the drivers and the biasing force cause the blades to move into a second subset of the bays and ii) after the blades enter the second subset of the bays, the biasing element pushing the shaft along a second direction opposite to the first direction such that the blades slide along the ramped surfaces of the first subset of the guide teeth until the blades abut the first vertical surfaces of the second subset of the guide teeth.

In some examples, when the fastener assembly is transitioning from the first state to the second state: i) the drivers push the blades along the first direction until the blades pass below the first vertical surfaces of the first subset of the guide teeth, ii) the first sloped surfaces and the second sloped surfaces engage with each other in a manner that urges the shaft to rotate about the vertical axis, and iii) the biasing force pushes the drivers along the second direction to retract the blades from the drivers and allow the second sloped surfaces and the ramped surfaces to engage in a manner that further urges the shaft to rotate about the vertical axis until the blades abut the first vertical surfaces of the second subset of the guide teeth. In one or more examples, the shaft rotates about 90 degrees to transition the fastener assembly between the first and second states. The method 900 ends at block 910.

Since a fastener assembly can be transitioned between first and second states merely by the application of force, there is no requirement for separate tools to fasten a riser cage assembly to an electronic device or release the riser cage assembly from the electronic device. Further, the riser cage assembly may be easily deployed in a chassis of the electronic device having space constraints as only the application of the force is all it requires on the fastener assembly to fasten the riser cage assembly to the electronic device or release the riser cage assembly from the electronic device. Accordingly, performing the maintenance or replacement activities of the riser cage assembly may not be a time-consuming and laborious activity, as it was previously while using screws and screwdriver to fasten a riser cage assembly to an electronic device or release the riser cage assembly from the electronic device.

In the foregoing description, numerous details are set forth to provide an understanding of the subject matter disclosed herein. However, implementation may be practiced without some or all of these details. Other implementations may include modifications, combinations, and variations from the details discussed above. It is intended that the following claims cover such modifications and variations.

What is claimed is:

1. A riser cage assembly for an electronic device, comprising:
a riser cage bracket configured to support a riser card; and
a fastener assembly coupled to the riser cage bracket and configured to removably fasten the riser cage bracket to the electronic device in an installed state of the riser cage assembly in the electronic device, the fastener assembly comprising:
an enclosure comprising a bore extending along a vertical axis, guide teeth within the bore, and bays defined between the guide teeth, wherein each of the guide teeth comprises a first vertical surface, a second vertical surface, and a ramped surface extending between the first and second vertical surfaces;
an actuator comprising drivers, wherein the actuator is movably coupled to a first end of the enclosure with the drivers disposed within the bore;
a shaft comprising blades and a locking arm, wherein the blades are disposed within the bore and the locking arm protrudes out of the bore beyond a second end of the enclosure, wherein the shaft is translatable along and rotatable about the vertical axis relative to the enclosure; and
a biasing element configured to generate a biasing force urging the shaft towards the first end of the enclosure,
wherein in a first state of the fastener assembly, the shaft is at a first rotational orientation and the blades are disposed within a first subset of the bays and abutting the first vertical surfaces of a first subset of the guide teeth;
wherein in a second state of the fastener assembly, the shaft is at a second rotational orientation and the blades are disposed within a second subset of the bays and abutting the first vertical surfaces of a second subset of the guide teeth;
wherein the fastener assembly can be transitioned from the first state to the second state by:
the actuator being pushed along a first direction such that the drivers push the blades in the first direction and compress the biasing element until the blades pass below the first vertical surfaces of the first subset of the guide teeth, whereupon the drivers and the biasing force cause the blades to move into the second subset of the bays; and
after the blades enter the second subset of the bays, the biasing element pushing the shaft along a second direction opposite to the first direction such that the blades slide along the ramped surfaces of the first subset of the guide teeth until the blades abut the first vertical surfaces of the second subset of the guide teeth.

2. The riser cage assembly of claim 1, wherein each of the bays comprises a vertical groove defined between the first vertical surface of one of the guide teeth and the second vertical surface of another of the guide teeth, and wherein the first vertical surface has a first height, and the second vertical surface has a second height smaller than the first height.

3. The riser cage assembly of claim 2, wherein, in the first state, the blades are positioned within the vertical grooves of the first subset of the bays.

4. The riser cage assembly of claim 3, wherein, in the first state, rotation of the shaft in any direction is prevented by the blades being within the vertical grooves of the first subset of the bays.

5. The riser cage assembly of claim 2, wherein the actuator comprises guides, each disposed within and movable along the vertical groove of one of the bays.

6. The riser cage assembly of claim 5, wherein the enclosure comprises blockers disposed within the vertical grooves of the second subset of the bays, and wherein the blockers are configured to block motion of the blades within the vertical grooves of the second subset of the bays while not blocking motion of the guides within the vertical grooves.

7. The riser cage assembly of claim 1,
wherein in the installed state of the riser cage assembly and the second state of the fastener assembly, the locking arm is engaged with a receptacle of the electronic device to removably fasten the riser cage bracket to the electronic device; and
wherein in the installed state of the riser cage assembly and the first state of the fastener assembly, the locking arm does not fasten the riser cage bracket to the electronic device.

8. The riser cage assembly of claim 7, wherein the fastener assembly further comprises a cover having an opening, coupled to the second end of the enclosure, wherein the shaft comprises a flange disposed above the locking arm, and wherein the biasing element is disposed around the shaft contacting the cover and the flange.

9. The riser cage assembly of claim 8, wherein the locking arm comprises a first set of protrusions, wherein, in the installed state of the riser cage assembly in the electronic device, the opening is aligned with a mounting hole of the riser cage bracket to allow the locking arm to protrude into the receptacle via the opening and the mounting hole, and the first set of protrusions to engage with a second set of protrusions of the receptacle in the second state of the fastener assembly, to removably fasten the riser cage bracket to the electronic device.

10. The riser cage assembly of claim 1, wherein the shaft rotates about 90 degrees to transition the fastener assembly between the first state and the second state.

11. The riser cage assembly of claim 1,
wherein each driver comprises a first sloped surface and each blade comprises a second sloped surface, where the first sloped surface, the second sloped surface, and the ramped surface of each guide tooth are complementary surfaces, and
wherein, when the fastener assembly is transitioning from the first state to the second state:
the drivers push the blades along the first direction until the blades pass below the first vertical surfaces of the first subset of the guide teeth;
the first sloped surfaces and the second sloped surfaces engage with each other in a manner that urges the shaft to rotate about the vertical axis; and
the biasing force pushes the drivers along the second direction to retract the blades from the drivers and allow the second sloped surfaces and the ramped surfaces to engage in a manner that further urges the shaft to rotate about the vertical axis until the blades abut the first vertical surfaces of the second subset of the guide teeth.

12. An electronic device comprising:
a chassis;
a receptacle coupled to the chassis; and
a riser cage assembly of claim 1, disposed on the electronic device such that a mounting hole of the riser cage bracket and an opening in a cover coupled to the fastener assembly are aligned with the receptacle to allow the locking arm to protrude into the receptacle via the opening and the mounting hole, and a first set of protrusions of the locking arm to engage with a second set of protrusions of the receptacle in the second state of the fastener assembly, to removably fasten the riser cage bracket to the electronic device.

13. The electronic device of claim 12, wherein each of the bays comprises a vertical groove defined between the first vertical surface of one of the guide teeth and the second vertical surface of another of the guide teeth, and wherein the first vertical surface has a first height, and the second vertical surface has a second height smaller than the first height.

14. The electronic device of claim 13, wherein in the first state, the blades are positioned within the vertical grooves of the first subset of the bays to prevent rotation of the shaft in any direction.

15. The electronic device of claim 13, wherein the actuator comprises guides, each disposed within and movable along the vertical groove of one of the bays, wherein the enclosure comprises blockers disposed within the vertical grooves of the second subset of the bays, and wherein the blockers are configured to block motion of the blades within the vertical grooves of the second subset of the bays while not blocking motion of the guides within the vertical grooves.

16. The electronic device of claim 12,
wherein in the installed state of the riser cage assembly and the second state of the fastener assembly, the locking arm is engaged with the receptacle to removably fasten the riser cage bracket to the electronic device; and
wherein in the installed state of the riser cage assembly and the first state of the fastener assembly, the locking arm does not fasten the riser cage bracket to the electronic device.

17. The electronic device of claim 12, wherein the shaft rotates about 90 degrees to transition the fastener assembly between the first state and the second state.

18. A method comprising:
disposing a riser cage bracket supporting a riser card, on a chassis of an electronic device such that a mounting hole of the riser cage bracket is aligned with a receptacle of the electronic device;
disposing a fastener assembly on the riser cage bracket such that an opening in the fastener assembly is aligned with the mounting hole of the riser cage bracket and a locking arm of the fastener assembly protrudes into the receptacle via the opening and the mounting hole,
wherein the fastener assembly comprises:
an enclosure comprising a bore extending along a vertical axis, guide teeth within the bore, and bays defined between the guide teeth, wherein each of the guide teeth comprises a first vertical surface, a second vertical surface, and a ramped surface extending between the first and second vertical surfaces;
an actuator comprising drivers, wherein the actuator is movably coupled to a first end of the enclosure with the drivers disposed within the bore;
a shaft comprising blades and the locking arm, wherein the blades are disposed within the bore and the locking arm protrudes out of the bore beyond a second end of the enclosure, wherein the shaft is translatable along and rotatable about the vertical axis relative to the enclosure; and
a biasing element configured to generate a biasing force urging the shaft towards the first end of the enclosure; and
driving the fastener assembly to transition from a first state to a second state to removably fasten the riser cage bracket to the electronic device, wherein driving the fastener assembly comprises:
pushing the actuator along a first direction such that the drivers push the blades in the first direction and compress the biasing element until the blades pass below the first vertical surfaces of a first subset of the guide teeth, whereupon the drivers and the biasing force cause the blades to move into a second subset of the bays; and
after the blades enter the second subset of the bays, the biasing element pushing the shaft along a second direction opposite to the first direction such that the blades slide along the ramped surfaces of the first subset of the guide teeth until the blades abut the first vertical surfaces of the second subset of the guide teeth.

19. The method of claim 18, wherein each driver comprises a first sloped surface and each blade comprises a second sloped surface, where the first sloped surface, the second sloped surface, and the ramped surface of each guide tooth are complementary surfaces, and
wherein, when the fastener assembly is transitioning from the first state to the second state:
the drivers push the blades along the first direction until the blades pass below the first vertical surfaces of the first subset of the guide teeth;
the first sloped surfaces and the second sloped surfaces engage with each other in a manner that urges the shaft to rotate about the vertical axis; and
the biasing force pushes the drivers along the second direction to retract the blades from the drivers and allow the second sloped surfaces and the ramped surfaces to engage in a manner that further urges the shaft to rotate about the vertical axis until the blades abut the first vertical surfaces of the second subset of the guide teeth.

20. The method of claim 18, wherein the shaft rotates about 90 degrees to transition the fastener assembly between the first state and the second state.
